(19) United States
(12) Patent Application Publication
(10) Pub. No.: US 2026/0093368 A1
(43) Pub. Date: Apr. 2, 2026

(54) WAVY ELECTRODES FOR REDUCED STRAIN TOUCH SENSOR PANEL

(71) Applicant: Apple Inc., Cupertino, CA (US)

(72) Inventors: Hongwoo JANG, Richland, WA (US); Isaac W. CHAN, San Jose, CA (US); Nikhil DOLE, Castro Valley, CA (US); Jiun-Jye CHANG, Cupertino, CA (US)

(21) Appl. No.: 19/327,823

(22) Filed: Sep. 12, 2025

Related U.S. Application Data
(60) Provisional application No. 63/700,251, filed on Sep. 27, 2024.

(51) Int. Cl. G06F 3/044; G06F 3/041; H10K 59/40; H10K 102/00

(52) U.S. Cl. CPC G06F 3/0448; G06F 3/0412; G06F 3/0445; G06F 3/0446; H10K 59/40; G06F 2203/04102; G06F 2203/04112; H10K 2102/311

(57) ABSTRACT

A foldable touch sensor panel includes a first plurality of touch electrodes along a first axis formed of a first conductive material disposed in a first conductive material layer and a second plurality of touch electrodes along a second axis formed of a second conductive material disposed in a second conductive material layer. In some examples, the first plurality of touch electrodes along the first axis is parallel to a folding axis of the touch sensor panel and are planar or non-planar. In some examples, the second plurality of touch electrodes along the second axis is non-parallel to the folding axis of the touch sensor panel and is at least partially non-planar.

### CROSS REFERENCE TO RELATED APPLICATIONS

This application claims the benefit of U.S. Provisional Application No. 63/700,251, filed September 27, 2024, the entire disclosure of which is herein incorporated by reference for all purposes.

### FIELD OF THE DISCLOSURE

This relates generally to touch sensor panels/screens, and more particularly to touch sensor panels/screens with non-planar electrode layers.

### BACKGROUND OF THE DISCLOSURE

Many types of input devices are presently available for performing operations in a computing system, such as buttons or keys, mice, trackballs, joysticks, touch sensor panels, touch screens and the like. Touch screens, in particular, are popular because of their ease and versatility of operation as well as their declining price. Touch screens can include a touch sensor panel, which can be a clear panel with a touch-sensitive surface, and a display device such as a liquid crystal display (LCD), light emitting diode (LED) display or organic light emitting diode (OLED) display that can be positioned partially or fully behind the panel so that the touch-sensitive surface can cover at least a portion of the viewable area of the display device. Touch screens can allow a user to perform various functions by touching the touch sensor panel using a finger, stylus or other object at a location often dictated by a user interface (UI) being displayed by the display device. In general, touch screens can recognize a touch and the position of the touch on the touch sensor panel, and the computing system can then interpret the touch in accordance with the display appearing at the time of the touch, and thereafter can perform one or more actions based on the touch. In the case of some touch sensing systems, a physical touch on the display is not needed to detect a touch. For example, in some capacitive-type touch sensing systems, fringing electrical fields used to detect touch can extend beyond the surface of the display, and objects approaching near the surface may be detected near the surface without actually touching the surface.

Capacitive touch sensor panels can be formed by a matrix of partially or fully transparent or non-transparent conductive plates (e.g., touch electrodes) made of materials such as Indium Tin Oxide (ITO). In some examples, the conductive plates can be formed from other materials including conductive polymers, metal mesh, graphene, nanowires (e.g., silver nanowires) or nanotubes (e.g., carbon nanotubes). It is due in part to their substantial transparency that some capacitive touch sensor panels can be overlaid on a display to form a touch screen, as described above. Some touch screens can be formed by at least partially integrating touch sensing circuitry into a display pixel stack-up (i.e., the stacked material layers forming the display pixels).

### SUMMARY OF THE DISCLOSURE

This relates to a touch screen including a display having an active area, a first metal layer and a second metal layer disposed over the display, and an intermediate dielectric layer, disposed between the first metal layer and the second metal layer. In some examples, a plurality of touch electrodes of the touch screen is formed in the active area of the display, the plurality of touch electrodes including a touch electrode formed from first metal mesh in the first metal layer and first metal mesh in the second metal layer.

The full descriptions of the examples are provided in the Drawings and the Detailed Description, and it is understood that the Summary of the Disclosure provided above does not limit the scope of the disclosure in any way.

### BRIEF DESCRIPTION OF THE DRAWINGS

FIGS. 1A-1E illustrate example systems that can include a touch screen according to examples of the disclosure.

FIG. 2 illustrates an example computing system including a touch screen according to examples of the disclosure.

FIG. 3A illustrates an example touch sensor circuit corresponding to a self-capacitance measurement of a touch node electrode and sensing circuit according to examples of the disclosure.

FIG. 3B illustrates an example touch sensor circuit corresponding to a mutual-capacitance drive line and sense line and sensing circuit according to examples of the disclosure.

FIG. 4A illustrates an example touch screen with touch electrodes arranged in rows and columns according to examples of the disclosure.

FIG. 4B illustrates an example touch screen with touch node electrodes arranged in a pixelated touch node electrode configuration according to examples of the disclosure.

FIG. 5 illustrates an example touch screen stack-up including a metal mesh layer according to examples of the disclosure.

FIG. 6A illustrates an example touch sensor panel with touch electrodes arranges in rows and columns according to examples of the disclosure.

FIG. 6B illustrates a close-up view of an example touch sensor panel with touch electrodes arranged in rows and columns according to examples of the disclosure.

FIG. 7 illustrates an example touch screen stack-up including a touch sensor panel according to examples of the disclosure.

FIG. 8A illustrates an example touch screen stack-up including a touch sensor panel with planar electrodes according to examples of the disclosure.

FIG. 8B illustrates an example stress/strain simulation of a folded touch screen stack-up including a touch sensor panel with planar electrodes according to examples of the disclosure.

FIG. 8C illustrates a close-up view of an example stress/strain simulation of a folded touch screen stack-up including a touch sensor panel with planar electrodes, focused on the touch sensor panel layers according to examples of the disclosure.

FIG. 9A illustrates an example touch screen stack-up including a touch sensor panel with non-planar electrodes according to examples of the disclosure.

FIG. 9B illustrates an example stress/strain simulation of a folded touch screen stack-up including a touch sensor panel with non-planar electrodes according to examples of the disclosure.

FIG. 9C illustrates a close-up view of an example stress/strain simulation of a folded touch screen stack-up including a touch sensor panel with non-planar electrodes, focused on the touch sensor panel layers according to examples of the disclosure.

### DETAILED DESCRIPTION

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples.

This relates to a touch screen including a display having an active area, a first metal layer and a second metal layer disposed over the display, and an intermediate dielectric layer, disposed between the first metal layer and the second metal layer. In some examples, a plurality of touch electrodes of the touch screen is formed in the active area of the display, the plurality of touch electrodes including a touch electrode formed from first metal mesh in the first metal layer and first metal mesh in the second metal layer.

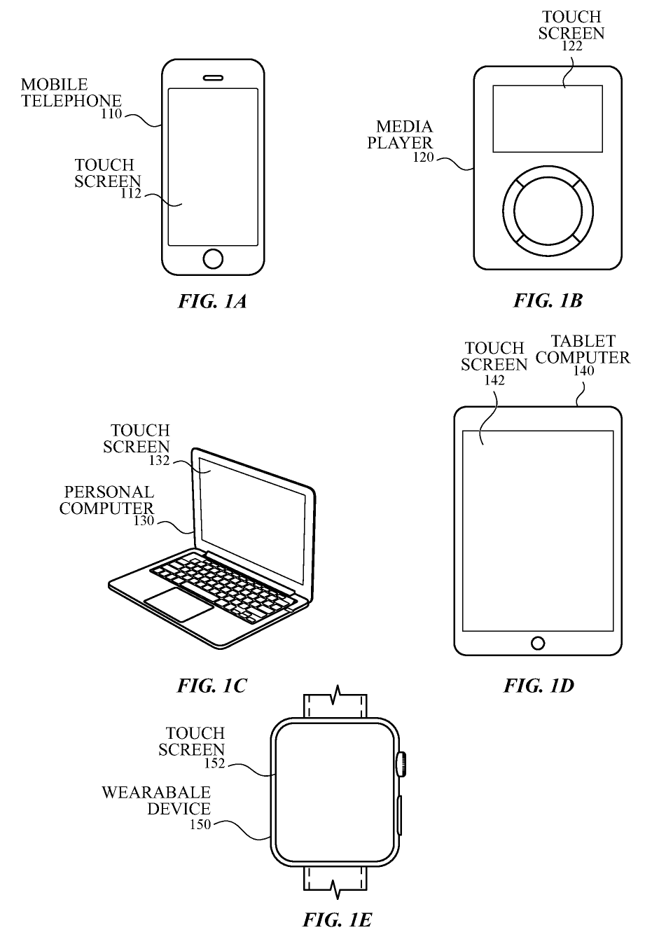

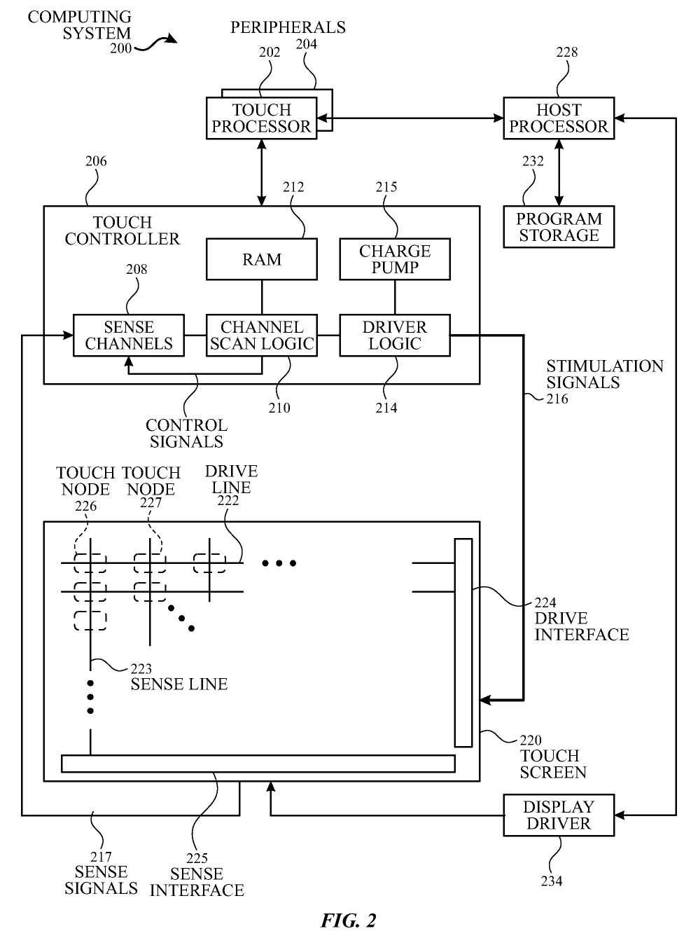

FIGS. 1A-1E illustrate example systems that can include a touch screen according to examples of the disclosure. FIG. 1A illustrates an example mobile telephone 110 that includes a touch screen 112 according to examples of the disclosure. FIG. 1B illustrates an example media player 120 that includes a touch screen 122 according to examples of the disclosure. FIG. 1C illustrates an example personal computer 130 that includes a touch screen 132 according to examples of the disclosure. FIG. 1D illustrates an example tablet computing device 140 that includes a touch screen 142 according to examples of the disclosure. FIG. 1E illustrates an example wearable device 150 that includes a touch screen 152 according to examples of the disclosure. It is understood that a touch screen can be implemented in other devices as well. In some examples, touch screens 112, 122, 132, 142, and 152, or a portion thereof, are foldable about one or more axes, as described in greater detail herein.

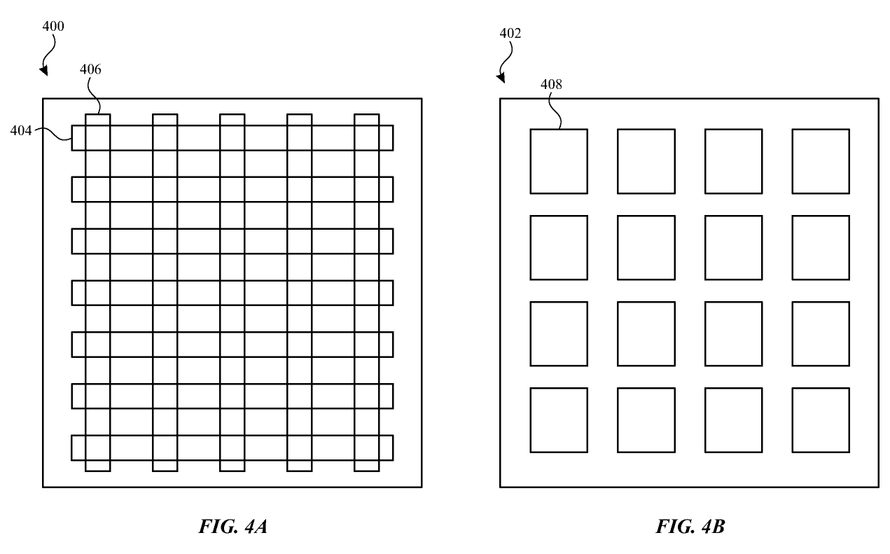

In some examples, touch screens 112, 122, 132, 142, and 152 can be based on self-capacitance. A self-capacitance based touch system can include a matrix of small, individual plates of conductive material or groups of individual plates of conductive material forming larger conductive regions that can be referred to as touch electrodes or as touch node electrodes (as described below with reference to FIG. 4B). For example, a touch screen can include a plurality of individual touch electrodes, each touch electrode identifying or representing a unique location (e.g., a touch node) on the touch screen at which touch or proximity is to be sensed, and each touch node electrode being electrically isolated from the other touch node electrodes in the touch screen/panel. Such a touch screen can be referred to as a pixelated self-capacitance touch screen, though it is understood that in some examples, the touch node electrodes on the touch screen can be used to perform scans other than self-capacitance scans on the touch screen (e.g., mutual capacitance scans). During operation, a touch node electrode can be stimulated with an alternating current (AC) waveform, and the self-capacitance to ground of the touch node electrode can be measured. As an object approaches the touch node electrode, the self-capacitance to ground of the touch node electrode can change (e.g., increase). This change in the self-capacitance of the touch node electrode can be detected and measured by the touch sensing system to determine the positions of multiple objects when they touch, or come in proximity to, the touch screen. In some examples, the touch node electrodes of a self-capacitance based touch system can be formed from rows and columns of conductive material, and changes in the self-capacitance to ground of the rows and columns can be detected, similar to above. In some examples, a touch screen can be multi-touch, single touch, projection scan, full-imaging multi-touch, capacitive touch, etc.

In some examples, touch screens 112, 122, 132, 142, and 152 can be based on mutual capacitance. A mutual capacitance based touch system can include electrodes arranged as drive and sense lines that may cross over each other on different layers (in a double-sided configuration), or may be adjacent to each other on the same layer (e.g., as described below with reference to FIG. 4A). The crossing or adjacent locations can form touch nodes. During operation, the drive line can be stimulated with an AC waveform and the mutual capacitance of the touch node can be measured. As an object approaches the touch node, the mutual capacitance of the touch node can change (e.g., decrease). This change in the mutual capacitance of the touch node can be detected and measured by the touch sensing system to determine the positions of multiple objects when they touch, or come in proximity to, the touch screen. As described herein, in some examples, a mutual capacitance based touch system can form touch nodes from a matrix of small, individual plates of conductive material.

In some examples, touch screens 112, 122, 132, 142, and 152 can be based on mutual capacitance and/or self-capacitance. The electrodes can be arranged as a matrix of small, individual plates of conductive material (e.g., as in touch node electrodes 408 in touch screen 402 in FIG. 4B) or as drive lines and sense lines (e.g., as in row touch electrodes 404 and column touch electrodes 406 in touch screen 400 in FIG. 4A), or in another pattern. The electrodes can be configurable for mutual capacitance or self-capacitance sensing or a combination of mutual and self-capacitance sensing. For example, in one mode of operation, electrodes can be configured to sense mutual capacitance between electrodes and in a different mode of operation, electrodes can be configured to sense self-capacitance of electrodes. In some examples, some of the electrodes can be configured to sense mutual capacitance therebetween and some of the electrodes can be configured to sense self-capacitance thereof.

FIG. 2 illustrates an example computing system including a touch screen according to examples of the disclosure. Computing system 200 can be included in, for example, a mobile phone, tablet, touchpad, portable or desktop computer, portable media player, wearable device or any mobile or non-mobile computing device that includes a touch screen or touch sensor panel. Computing system 200 can include a touch sensing system including one or more touch processors 202, peripherals 204, a touch controller 206, and touch sensing circuitry (described in more detail below). Peripherals 204 can include, but are not limited to, random access memory (RAM) or other types of memory or storage, watchdog timers and the like. Touch controller 206 can include, but is not limited to, one or more sense channels 208, channel scan logic 210 and driver logic 214. Channel scan logic 210 can access RAM 212, autonomously read data from the sense channels and provide control for the sense channels. In addition, channel scan logic 210 can control driver logic 214 to generate stimulation signals 216 at various frequencies and/or phases that can be selectively applied to drive regions of the touch sensing circuitry of touch screen 220, as described in more detail below. In some examples, touch controller 206, touch processor 202 and peripherals 204 can be integrated into a single application specific integrated circuit (ASIC), and in some examples can be integrated with touch screen 220 itself.

It should be apparent that the architecture shown in FIG. 2 is only one example architecture of computing system 200, and that the system could have more or fewer components than shown, or a different configuration of components. In some examples, computing system 200 can include an energy storage device (e.g., a battery) to provide a power supply and/or communication circuitry to provide for wired or wireless communication (e.g., cellular, Bluetooth, Wi-Fi, etc.). The various components shown in FIG. 2 can be implemented in hardware, software, firmware or any combination thereof, including one or more signal processing and/or application specific integrated circuits.

Computing system 200 can include a host processor 228 for receiving outputs from touch processor 202 and performing actions based on the outputs. For example, host processor 228 can be connected to program storage 232 and a display controller/driver 234 (e.g., a Liquid-Crystal Display (LCD) driver). It is understood that although some examples of the disclosure may be described with reference to LCD displays, the scope of the disclosure is not so limited and can extend to other types of displays, such as Light-Emitting Diode (LED) displays, including Organic LED (OLED), Active-Matrix Organic LED (AMOLED) and Passive-Matrix Organic LED (PMOLED) displays. Display driver 234 can provide voltages on select (e.g., gate) lines to each pixel transistor and can provide data signals along data lines to these same transistors to control the pixel display image.

Host processor 228 can use display driver 234 to generate a display image on touch screen 220, such as a display image of a user interface (UI), and can use touch processor 202 and touch controller 206 to detect a touch on or near touch screen 220, such as a touch input to the displayed UI. The touch input can be used by computer programs stored in program storage 232 to perform actions that can include, but are not limited to, moving an object such as a cursor or pointer, scrolling or panning, adjusting control settings, opening a file or document, viewing a menu, making a selection, executing instructions, operating a peripheral device connected to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. Host processor 228 can also perform additional functions that may not be related to touch processing.

Note that one or more of the functions described herein, can be performed by firmware stored in memory (e.g., one of the peripherals 204 in FIG. 2) and executed by touch processor 202, or stored in program storage 232 and executed by host processor 228. The firmware can also be stored and/or transported within any non-transitory computer-readable storage medium for use by or in connection with an instruction execution system, apparatus, or device, such as a computer-based system, processor-containing system, or other system that can fetch the instructions from the instruction execution system, apparatus, or device and execute the instructions. In the context of this document, a “non-transitory computer-readable storage medium” can be any medium (excluding signals) that can contain or store the program for use by or in connection with the instruction execution system, apparatus, or device. In some examples, RAM 212 or program storage 232 (or both) can be a non-transitory computer readable storage medium. One or both of RAM 212 and program storage 232 can have stored therein instructions, which when executed by touch processor 202 or host processor 228 or both, can cause the device including computing system 200 to perform one or more functions and methods of one or more examples of this disclosure. The computer-readable storage medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a compact disc (CD), CD-R, CD-RW, digital video disc (DVD), DVD-R, or DVD-RW, or flash memory such as compact flash cards, secured digital cards, universal serial bus (USB) memory devices, memory sticks, and the like.

The firmware can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport medium can include, but is not limited to, an electronic, magnetic, optical, electromagnetic or infrared wired or wireless propagation medium.

Touch screen 220 can be used to derive touch information at multiple discrete locations of the touch screen, referred to herein as touch nodes. Touch screen 220 can include touch sensing circuitry that can include a capacitive sensing medium having a plurality of drive lines 222 and a plurality of sense lines 223. It should be noted that the term “lines” is sometimes used herein to mean simply conductive pathways, as one skilled in the art will readily understand, and is not limited to elements that are strictly linear, but includes pathways that change direction, and includes pathways of different size, shape, materials, etc. Drive lines 222 can be driven by stimulation signals 216 from driver logic 214 through a drive interface 224, and resulting sense signals 217 generated in sense lines 223 can be transmitted through a sense interface 225 to sense channels 208 in touch controller 206. In this way, drive lines and sense lines can be part of the touch sensing circuitry that can interact to form capacitive sensing nodes, which can be thought of as touch picture elements (touch pixels) and referred to herein as touch nodes, such as touch nodes 226 and 227. This way of understanding can be particularly useful when touch screen 220 is viewed as capturing an “image” of touch (“touch image”). In other words, after touch controller 206 has determined whether a touch has been detected at each touch nodes in the touch screen, the pattern of touch nodes in the touch screen at which a touch occurred can be thought of as an “image” of touch (e.g., a pattern of fingers touching the touch screen). As used herein, an electrical component “coupled to” or “connected to” another electrical component encompasses a direct or indirect connection providing electrical path for communication or operation between the coupled components. Thus, for example, drive lines 222 may be directly connected to driver logic 214 or indirectly connected to driver logic 214 via drive interface 224 and sense lines 223 may be directly connected to sense channels 208 or indirectly connected to sense channels 208 via sense interface 225. In either case an electrical path for driving and/or sensing the touch nodes can be provided.

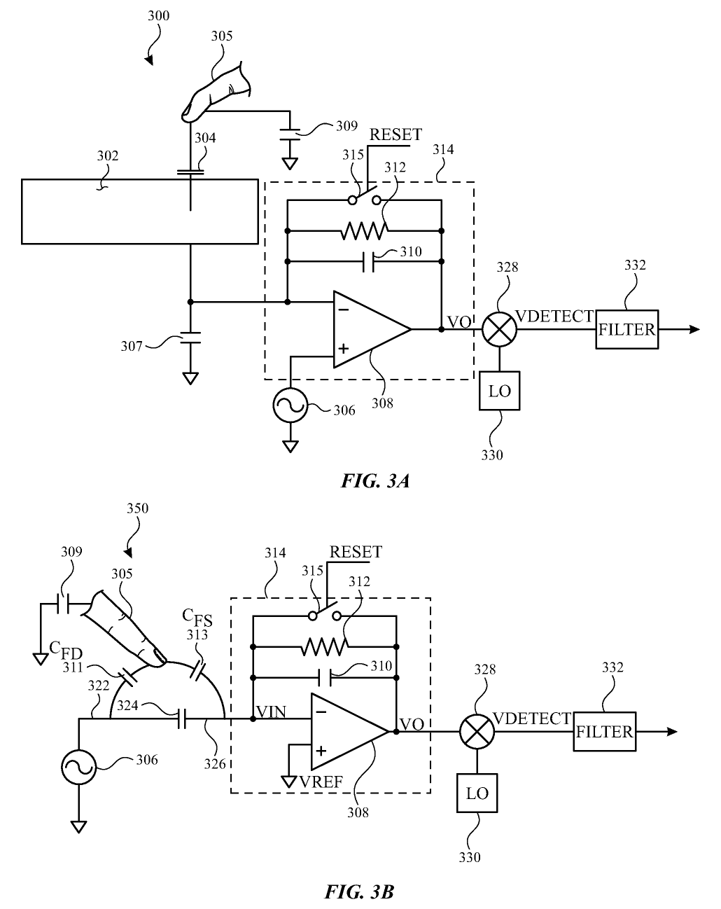

FIG. 3A illustrates an exemplary touch sensor circuit 300 corresponding to a self-capacitance measurement of a touch node electrode 302 and sensing circuit 314 according to examples of the disclosure. Touch node electrode 302 can correspond to a touch electrode 404 or 406 of touch screen 400 or a touch node electrode 408 of touch screen 402. Touch node electrode 302 can have an inherent self-capacitance to ground associated with it, and also an additional self-capacitance to ground that is formed when an object, such as finger 305, is in proximity to or touching the electrode. The total self-capacitance to ground of touch node electrode 302 can be illustrated as capacitance 304. Touch node electrode 302 can be coupled to sensing circuit 314. Sensing circuit 314 can include an operational amplifier 308, feedback resistor 312 and feedback capacitor 310, although other configurations can be employed. For example, feedback resistor 312 can be replaced by a switched capacitor resistor in order to minimize a parasitic capacitance effect that can be caused by a variable feedback resistor. Touch node electrode 302 can be coupled to the inverting input (-) of operational amplifier 308. An AC voltage source (V_{ac}) corresponding to stimulation signal 306 can be coupled to the non-inverting input (+) of operational amplifier 308. Touch sensor circuit 300 can be configured to sense changes (e.g., increases) in the total self-capacitance 304 of the touch node electrode 302 induced by a finger or object either touching or in proximity to the touch sensor panel. Output 320 can be used by a processor to determine the presence of a proximity or touch event, or the output can be inputted into a discrete logic network to determine the presence of a proximity or touch event.

FIG. 3B illustrates an exemplary touch sensor circuit 350 corresponding to a mutual-capacitance drive line 322 and sense line 326 and sensing circuit 314 according to examples of the disclosure. Drive line 322 can be stimulated by stimulation signal 306 (e.g., an AC voltage signal). Stimulation signal 306 can be capacitively coupled to sense line 326 through mutual capacitance 324 between drive line 322 and the sense line. When a finger 305 or object approaches the touch node created by the intersection of drive line 322 and sense line 326, mutual capacitance 324 can change (e.g., decrease) (e.g., due to capacitive coupling indicated by capacitances C_{FD}311 and C_{FS}313, which can be formed between drive line 322, finger 305 and sense line 326). This change in mutual capacitance 324 can be detected to indicate a touch or proximity event at the touch node, as described herein. The sense signal coupled onto sense line 326 can be received by sensing circuit 314. Sensing circuit 314 can include operational amplifier 308 and at least one of a feedback resistor 312 and a feedback capacitor 310. FIG. 3B illustrates a general case in which both resistive and capacitive feedback elements are utilized. The sense signal (referred to as Vin) can be inputted into the inverting input of operational amplifier 308, and the non-inverting input of the operational amplifier can be coupled to a reference voltage V_{ref}. Operational amplifier 308 can drive its output to voltage Vₒ to keep Vᵢₙ substantially equal to V_{ref}, and can therefore maintain Vᵢₙ constant or virtually grounded. A person of skill in the art would understand that in this context, equal can include deviations of up to 15%. Therefore, the gain of sensing circuit 314 can be mostly a function of the ratio of mutual capacitance 324 and the feedback impedance, comprised of resistor 312 and/or capacitor 310. The output of sensing circuit 314 Vo can be filtered and heterodyned or homodyned by being fed into multiplier 328, where Vo can be multiplied with local oscillator 330 to produce V_{detect}. V_{detect} can be inputted into filter 332. One skilled in the art will recognize that the placement of filter 332 can be varied; thus, the filter can be placed after multiplier 328, as illustrated, or two filters can be employed: one before the multiplier and one after the multiplier. In some examples, there can be no filter at all. The direct current (DC) portion of V_{detect} can be used to determine if a touch or proximity event has occurred. Note that while FIGS. 3A-3B indicate the demodulation at multiplier 328 occurs in the analog domain, output Vo may be digitized by an analog-to-digital converter (ADC), and blocks corresponding to multiplier 328, filter 332 and local oscillator 330 may be implemented in a digital fashion (e.g., 328 can be a digital demodulator, 332 can be a digital filter, and 330 can be a digital NCO (Numerical Controlled Oscillator).

Referring back to FIG. 2, in some examples, touch screen 220 can be an integrated touch screen in which touch sensing circuit elements of the touch sensing system can be integrated into the display pixel stack-ups of a display. The circuit elements in touch screen 220 can include, for example, elements that can exist in LCD or other displays (LED display, OLED display, etc.), such as one or more pixel transistors (e.g., thin film transistors (TFTs)), gate lines, data lines, pixel electrodes and common electrodes. In a given display pixel, a voltage between a pixel electrode and a common electrode can control a luminance of the display pixel. The voltage on the pixel electrode can be supplied by a data line through a pixel transistor, which can be controlled by a gate line. It is noted that circuit elements are not limited to whole circuit components, such as a whole capacitor, a whole transistor, etc., but can include portions of circuitry, such as only one of the two plates of a parallel plate capacitor.

FIG. 4A illustrates touch screen 400 with touch electrodes 404 and 406 arranged in rows and columns according to examples of the disclosure. Specifically, touch screen 400 can include a plurality of touch electrodes 404 disposed as rows, and a plurality of touch electrodes 406 disposed as columns. Touch electrodes 404 and touch electrodes 406 can be on the same or different material layers on touch screen 400, and can intersect with each other, as illustrated in FIG. 4A. In some examples, the electrodes can be formed on opposite sides of a transparent (partially or fully) substrate and from a transparent (partially or fully) semiconductor material, such as indium tin oxide (ITO), though other materials are possible. Electrodes displayed on layers on different sides of the substrate can be referred to herein as a double-sided sensor. In some examples, touch screen 400 can sense the self-capacitance of touch electrodes 404 and 406 to detect touch and/or proximity activity on touch screen 400, and in some examples, touch screen 400 can sense the mutual capacitance between touch electrodes 404 and 406 to detect touch and/or proximity activity on touch screen 400.

Although FIG. 4A illustrates touch electrodes 404 and touch electrodes 406 as rectangular electrodes, in some examples, other shapes and configurations are possible for row and column electrodes. For example, in some examples, some or all row and column electrodes can be formed from multiple touch electrodes formed on one side of substrate from a transparent (partially or fully) semiconductor material. The touch electrodes of a particular row or column can be interconnected by coupling segments and/or bridges. Row and column electrodes formed in a layer on the same side of a substrate can be referred to herein as a single-sided sensor. As described in more detail below, row and column electrodes can have other shapes. Additionally, although primarily described in terms of a row-column configuration, it is understood that in some examples, the same principles can be applied to two-axis array of touch nodes in a non-rectilinear arrangement.

FIG. 4B illustrates touch screen 402 with touch node electrodes 408 arranged in a pixelated touch node electrode configuration according to examples of the disclosure. Specifically, touch screen 402 can include a plurality of individual touch node electrodes 408, each touch node electrode identifying or representing a unique location on the touch screen at which touch or proximity (e.g., a touch or proximity event) is to be sensed, and each touch node electrode being electrically isolated from the other touch node electrodes in the touch screen/panel, as previously described. Touch node electrodes 408 can be on the same or different material layers on touch screen 402. In some examples, touch screen 402 can sense the self-capacitance of touch node electrodes 408 to detect touch and/or proximity activity on touch screen 402, and in some examples, touch screen 402 can sense the mutual capacitance between touch node electrodes 408 to detect touch and/or proximity activity on touch screen 402.

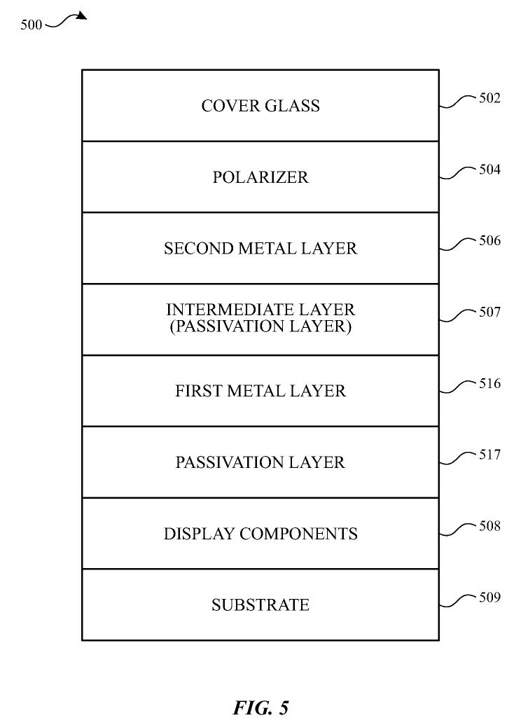

In some examples, some or all of the touch electrodes of a touch screen can be formed from a metal mesh in one or more layers. FIG. 5 illustrates an example touch screen stack-up including a metal mesh layer according to examples of the disclosure. Touch screen 500 can include a substrate 509 (e.g., a printed circuit board) upon which display components 508 (e.g., LEDs or other light emitting components and circuitry) can be mounted. In some examples, the display components 508 can be partially or fully embedded in substrate 509 (e.g., the components can be placed in depressions in the substrate). Substrate 509 can include routing traces in one or more layers to route the display components (e.g., LEDs) to display driving circuitry (e.g., display driver 234). The stack-up of touch screen 500 can also include one or more passivation layers deposited over the display components 508. For example, the stack-up of touch screen 500 illustrated in FIG. 5 can include an intermediate layer / passivation layer 507 (e.g., transparent epoxy), between metal layers (e.g., first metal mesh layer 516 and second metal mesh layer 506), and passivation layer 517. Additionally or alternatively, the stack-up of touch screen 500 illustrated in FIG. 5 can include a passivation layer (not shown) between second metal mesh layer 506 and polarizer 504. Passivation layers 507 and 517 can planarize the surface for respective metal mesh layers. Additionally, the passivation layers can provide electrical isolation (e.g., between metal mesh layers and between the LEDs and a metal mesh layer). Metal mesh layer 516 (e.g., copper, silver, etc.) can be deposited on the planarized surface of the passivation layer 517 over the display components 508, and metal mesh layer 506 (e.g., copper, silver, etc.) can be deposited on the planarized surface of passivation layer 507. In some examples, the passivation layer 517 can include material to encapsulate the display components to protect them from corrosion or other environmental exposure. Metal mesh layer 506 and/or metal mesh layer 516 can include a pattern of conductor material in a mesh pattern. In some examples, metal mesh layer 506 and metal mesh layer 516 can be coupled by one or more vias (e.g., through intermediate layer / passivation layer 507. Additionally, although not shown in FIG. 5, a border region around the display active area can include metallization (or other conductive material) that may or may not be a metal mesh pattern. In some examples, metal mesh is formed of a non-transparent material, but the metal mesh wires are sufficiently thin and sparse to appear transparent to the human eye. The touch electrodes (and some routing) as described herein can be formed in the metal mesh layer(s) from portions of the metal mesh. In some examples, polarizer 504 can be disposed above the metal mesh layer 506 (optionally with another planarization layer disposed over the metal mesh layer 506). In some examples, polarizer 504 includes a color filter. In some examples, polarizer 504 is replaced in the stack-up by a color filter (optionally with the polarizer disposed in a different layer of the stack-up). Cover glass (or front crystal) 502 can be disposed over polarizer 504 and form the outer surface of touch screen 500. It is understood that although two metal mesh layers (and two corresponding planarization layers) are illustrated, in some examples more or fewer metal mesh layers (and corresponding planarization layers) can be implemented. Additionally, it is understood that in some examples, display components 508, substrate 509 and/or passivation layer 517 can be replaced by a thin-film transistor (TFT) LCD display (or other types of displays), in some examples. Additionally, it is understood that polarizer 504 can include one or more transparent layers including a polarizer, adhesive layers (e.g., optically clear adhesive) and protective layers.

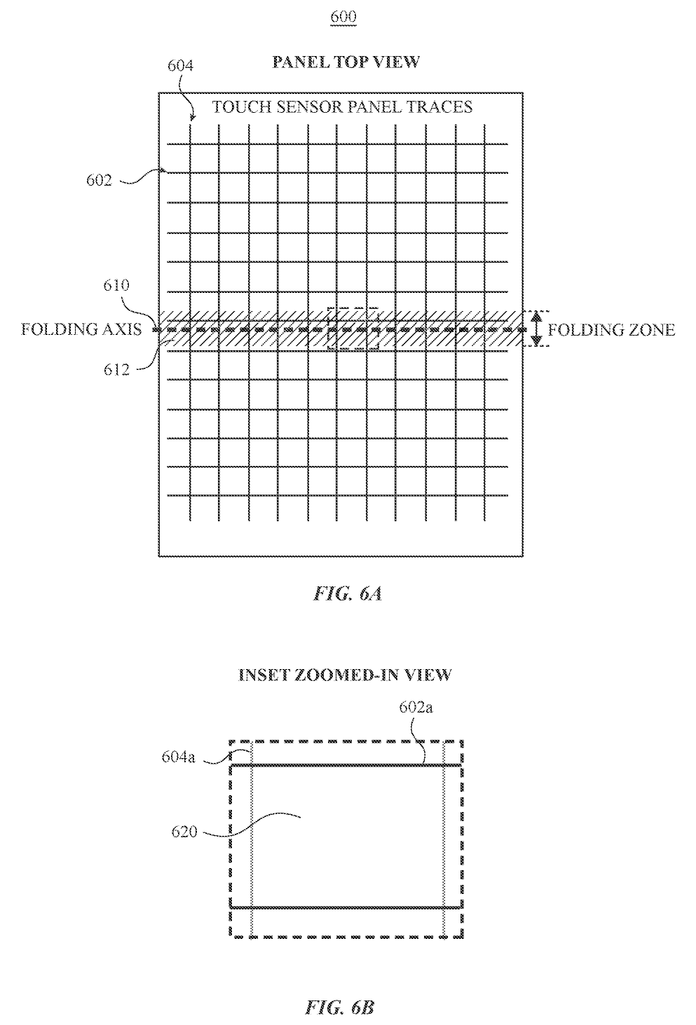

As described herein, in some examples, the touch sensor panel or touch screen is foldable about a folding axis (e.g., folding axis 610). FIG. 6A illustrates touch sensor panel 600 with touch electrodes 602 and 604 arranged in rows and columns according to examples of the disclosure. Specifically, touch sensor panel 600 can include a plurality of touch electrodes 602 disposed as row touch electrodes, and a plurality of touch electrodes 604 disposed as column touch electrodes. Touch electrodes 602 and touch electrodes 604 can be disposed in the same layer (e.g., using bridges) or disposed in different material layers of touch sensor panel 600, and touch nodes are formed at adjacencies or at intersections of touch electrodes, as illustrated in FIG. 6A. In some examples, the touch electrodes can be formed on opposite sides of a transparent (partially or fully) substrate, which serves as a dielectric. In some examples, the touch electrodes can be formed from transparent (partially or fully) conductors, such as ITO, though other materials are possible. In some examples, touch sensor panel 600 can sense the self-capacitance of touch electrodes 602 and 604 to detect touch and/or proximity activity on touch sensor panel 600, and in some examples, touch sensor panel 600 can sense the mutual capacitance between touch electrodes 602 and 604 to detect touch and/or proximity activity on touch sensor panel 600. In some examples, the touch electrodes of a particular row or column can be interconnected by coupling segments and/or bridges.

In some examples, touch electrodes 602 and touch electrodes 604 are arranged in a grid pattern where electrodes are aligned parallel to two distinct axes. For example, touch electrodes 602 may be disposed along a first axis (e.g., a horizontal axis or X-axis) and touch electrodes 604 may be disposed along a second axis (e.g., a vertical axis or Y-axis). In some examples, other configurations of electrodes are possible to enhance touch detection in devices with curved or non-rectangular screens, such as radial, circular, or hexagonal patterns. In some examples, electrodes along one axis may be positioned on a different layer relative to electrodes along the other axis to reduce cross-talk and improve the reliability of touch sensing. In some examples, different materials may be used for electrodes along each axis to increase transparency, conductivity, or flexibility.

In some examples, the conductive materials used for the electrodes in touch sensor panel 600 include materials capable of conducting electricity, chosen based on properties such as conductivity, transparency, flexibility, and durability. Some example materials include, but are not limited to, Indium Tin Oxide (ITO), metal mesh (e.g., fine wires of gold, silver, or copper), conductive polymers (e.g., Poly(3,4-ethylenedioxythiophene) (PEDOT)), carbon nanotubes, or silver nanowires.

In some examples, the touch sensor panel 600 includes one or more conductive material layers specifically designed to include and/or support the conductive electrodes necessary for touch functionality. In some examples, the conductive material layer is a single homogeneous layer of material, such as a thin film of ITO or a sheet of metal mesh that is patternable to form conductive electrodes of touch sensor panel 600. In some examples, the conductive material layer consists of a plurality of sub-layers, each contributing different properties to the electrodes. For example, a base layer may be used for structural support and a top layer for conductivity and touch sensitivity. In some examples, the conductive material layer is integrated directly above or below other functional layers within touch sensor panel 600, such as dielectric layers or barrier layers. In some examples, the conductive material layer is designed to maintain relatively high levels of electrical performance when bent or folded. For instance, this may involve structuring the conductive layer in a way that allows deformation without fracturing, such as through the use of a wavy pattern, as described in greater detail herein.

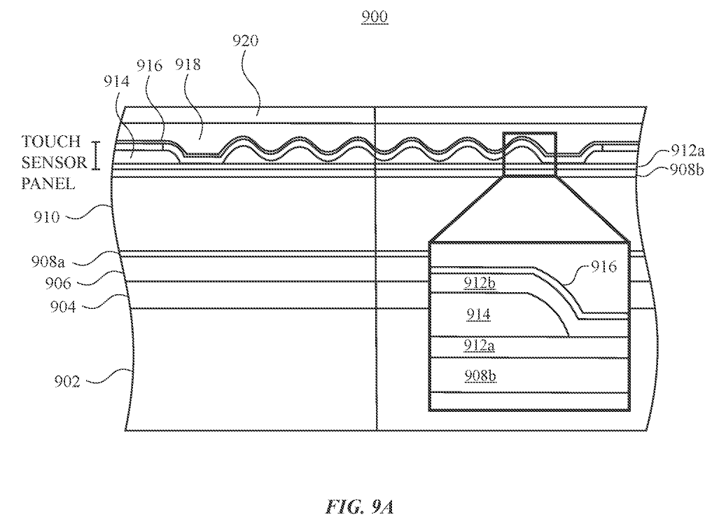

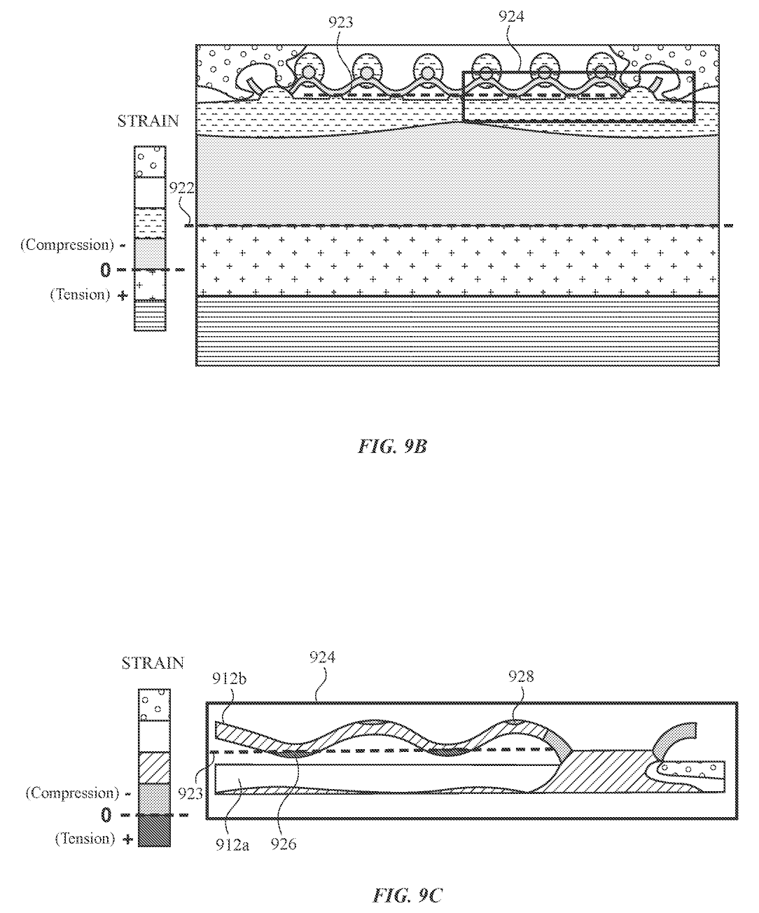

In some examples, folding axis 610 of touch sensor panel 600 refers to a predefined line or axis about which touch sensor panel 600 and the overall display are designed to fold. In some examples, folding axis 610 corresponds to a mechanical hinge or bending point that allows the electronic device to transition between folded and unfolded states. In some examples, folding axis 610 is centrally located across the device to facilitate a symmetrical fold. In some examples, folding axis 610 is positioned off-center or near one edge of the device, enabling a fold that leaves part of the display exposed for quick access to notifications or controls. In some examples, folding axis 610 is reinforced with specialized materials or structures to withstand the mechanical stress of repeated folding and unfolding, such as flexible adhesives, elastic polymers, or composite materials that enhance durability without compromising the flexibility of touch sensor panel 600. In some examples, the configuration of touch electrodes 602 and/or touch electrodes 604 in relation to folding axis 610 is designed to ensure continuous functionality regardless of the folding state of touch sensor panel 600, as described in greater detail herein. For example, touch electrodes 602 parallel to folding axis 610 may be made planar or to have minimal topographical features to reduce complexity and potential stress points, whereas touch electrodes 604 orthogonal to folding axis 610 may feature non-planar, resilient designs, such as wavy patterns, to accommodate the mechanical deformation during folding, as described in greater detail with respect to FIGS. 9A-9C.

In some examples, a folding zone 612 of touch sensor panel 600 refers to the area immediately surrounding folding axis 610, where touch sensor panel 600 is designed to bend or fold. In some examples, folding zone 612 undergoes the most mechanical stress during the bending process, as described in greater detail with respect to FIGS. 9A-9C. In some examples, touch electrodes 604 may feature non-planar designs, such as wavy patterns, within folding zone 612 and planar designs outside of folding zone 612.

FIG. 6B illustrates a close-up view of touch sensor panel 600 with touch electrodes 602 and 604 arranged in rows and columns according to examples of the disclosure. In FIG. 6B, the dimensions and spacing of components are intentionally exaggerated to illustrate the features and arrangement of the touch electrodes and grey area 620 within touch sensor panel 600. In some examples, grey area 620 represents an OLED emissive area where no electrodes are present to allow light from the OLED components to pass through unobstructed, enhancing display clarity and color accuracy. In some examples, grey area 620 is devoid of any conductive materials or patterns that could disrupt the visual output. In some examples, grey area 620 is surrounded by a perimeter of active touch electrodes 602a and 604a that do not overlap with the emissive zones but are close enough to accurately detect touch interactions near on or around grey area 620. As described above with reference to FIG. 6A, horizontal touch electrodes 602 may be planar, while vertical touch electrodes 604 orthogonal to folding axis 610 may feature non-planar designs, such as wavy patterns, to accommodate the mechanical deformation during folding.

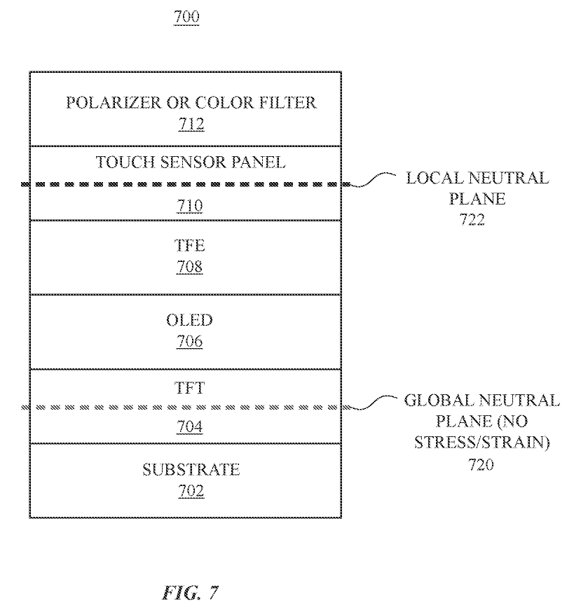

FIG. 7 illustrates an example touch screen stack-up including a touch sensor panel according to examples of the disclosure. In some examples, touch screen 700 has one or more characteristics of touch screen 500 of FIG. 5. In some examples, touch screen 700 includes a substrate layer 702 (e.g., polyethylene terephthalate, a printed circuit board, etc.) upon which display components can be formed or mounted. In some examples, the display components can be partially or fully embedded in substrate layer 702. In some examples, substrate layer 702 includes routing traces in one or more layers to route the display components to display driving circuitry (e.g., display driver 234). In some examples, touch screen 700 includes a thin film transistor (TFT) layer 704 consisting of an array of thin film transistors that are used to control the pixels in the display. In some examples, touch screen 700 includes an OLED layer 706 composed of organic compounds that emit light to generate the visual output of the display. In some examples, touch screen 700 includes a thin film encapsulation (TFE) layer 708 that is designed to protect OLED layer 706 from environmental factors such as moisture and oxygen. In some examples, touch screen 700 includes a touch sensor panel layer 710 that includes one or more conductive layers in which the touch-sensing electrodes are disposed, such as touch electrodes 602 and/or 604 of FIG. 6A. In some examples, touch sensor panel layer 710 has one or more characteristics of touch sensor panel 600 of FIG. 6A. In some examples, touch sensor panel layer 710 is formed as an on-cell touch sensor panel in which the touch conductive layers are formed over the display (e.g., rather than forming the touch sensor panel and display separately and then laminating these together to form the touch screen). In some examples, touch screen 700 includes a polarizer layer 712 designed to improve the visibility and quality of the display by reducing glare and enhancing contrast.

FIG. 7 illustrates touch screen 700 with one or more neutral planes. Within the context of this disclosure, a neutral plane within a display panel stack-up refers to a conceptual layer or region where the mechanical stress and strain are reduced (or zero) during bending or folding compared to other regions of the stack-up. In some examples, touch screen 700 includes a global neutral plane 720 which defines a layer that exhibits a lowest average strain across touch screen 700 during bending or folding. In some examples, global neutral plane 720 is located within TFT layer 704, as illustrated in FIG. 7. However, global neutral plane 720 may be located in different layers of touch screen 700, such as OLED layer 706. In some examples, global neutral plane 720 is designed to be located within TFT layer 704 by adjusting the thickness and/or composition of the layers above and/or below TFT layer 704. In some examples, touch screen 700 includes a 3D local neutral plane 722 within touch sensor panel layer 710 which defines a layer that exhibits a relatively low average strain compared to different layers of touch screen 700. In some examples, the average strain at 3D local neutral plane 722 is greater than the average strain at global neutral plane 720, as described in greater detail with respect to FIGS. 9A-9C. In some examples, 3D local neutral plane 722 is achieved through a wavy pattern engineered into touch sensor panel layer 710, which allows the material to accommodate bending and folding by distributing mechanical forces more evenly across the layer (e.g., more degrees of freedom for deformation), as described in greater detail with respect to FIGS. 9A-9C.

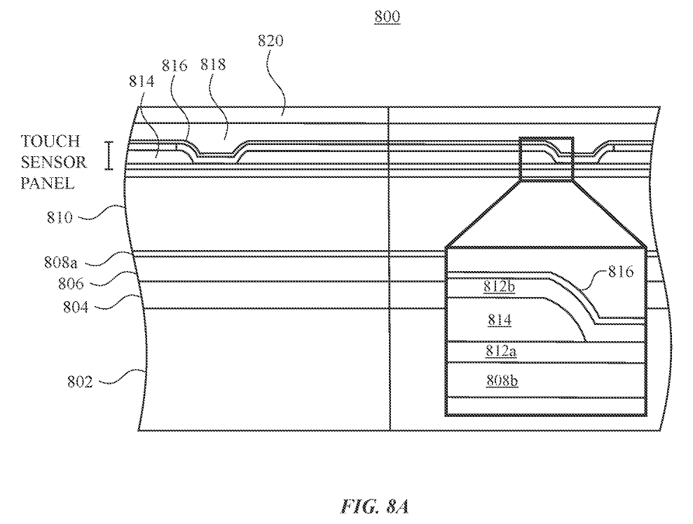

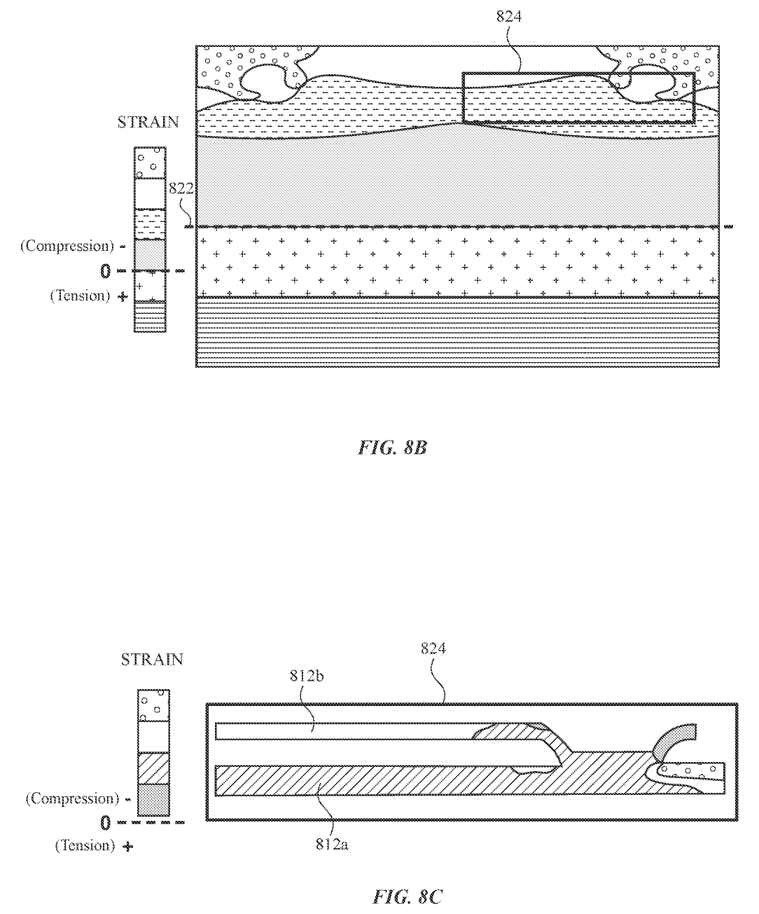

FIG. 8A illustrates an example touch screen stack-up including a touch sensor panel with planar electrodes according to examples of the disclosure. In some examples, touch screen 800 has one or more characteristics of touch screen 500 of FIG. 5 and/or touch screen 700 of FIG. 7. In some examples, touch screen 800 includes a substrate layer 802 (e.g., polyimide, polyethylene terephthalate, a printed circuit board, etc.) upon which display components can be formed or mounted. In some examples, the display components can be partially or fully embedded in substrate layer 802. In some examples, substrate layer 802 includes routing traces in one or more layers to route the display components to display driving circuitry (e.g., display driver 234). In some examples, touch screen 800 includes a TFT bottom layer 804 and a TFT top layer 806 referring to distinct sections of a TFT assembly that control the operation of the display pixels. In some examples, TFT bottom layer 804 and TFT top layer 806 have different characteristics. For example, TFT bottom layer 804 may house the main gate drivers and source lines necessary for controlling the basic on/off functionality of the pixels, while TFT bottom layer 806 may contain more refined control mechanisms, such as capacitors or additional transistors, which fine-tune the pixel operation for color accuracy and response time. In some examples, touch screen 800 includes a first passivation layer 808a, an encapsulation layer 810, and a second passivation layer 808b, that serve as protective layers within the stack-up, shielding the underlying electronic components from environmental factors. In some examples, passivation layers 808a and 808b differ in material composition to perform different protective roles.

In some examples, touch screen 800 includes a first touch metal layer 812a, which is one of the conductive layers within the stack-up. In some examples, electrodes formed on first touch metal layer 812a have one or more characteristics of touch electrodes 602 of FIG. 6A. In some examples, touch screen 800 includes a second touch metal layer 812b, which is one of the conductive layers within the stack-up. In some examples, second touch metal layer 812b has one or more characteristics of touch electrodes 604 of FIG. 6A. In some examples, first touch metal layer 812a and second touch metal layer 812b are planar, meaning that they consist of relatively flat, uniformly thick layers of conductive material without any intentional topographical variations such as ridges or waves. In some examples, touch screen 800 includes an organic thin inter-layer dielectric (OTILD) 814, which acts as an insulating layer within the stack-up. In some examples, OTILD 814 is positioned between two conductive layers, such as first touch metal layer 812a and second touch metal layer 812b and prevents electrical crosstalk and short circuits between these conductive layers.

In some examples, touch screen 800 includes a color filter/black matrix (CF/BM) layer 818. In some examples, a color filter portion of CF/BM layer 818 includes arrays of red, green, and blue subpixels that filter the white light emitted from the underlying layers into the primary colors needed for full-color display. In some examples, a black matrix portion of CF/BM layer 818 surrounds each subpixel to absorb stray light to enhance the contrast and sharpness of the image by preventing light from leaking between subpixels. In some examples, touch screen 800 includes a passivation layer 816 (also referred to as a color buffer layer), which optionally manages and enhances the optical characteristics of the display by filtering and/or adjusting the light before it passes through CF/BM layer 818 to ensure the colors displayed are vibrant, accurate, and uniform across the screen. In some examples, passivation layer 816 is positioned between second touch metal layer 812b and color filter layer 818. In some examples, touch screen 800 includes an over coat (OC) layer 820 (also referred to as a cover layer, cover substrate, or cover glass), which is the topmost layer in the stack-up of touch screen 800 and serves as a protective covering for the entire display assembly beneath it. In some examples, OC layer 820 is made from durable, transparent materials such as glass (e.g., hardened glass) or clear polymer composites that offer high resistance to scratches, impacts, and abrasion.

FIG. 8B illustrates an example stress/strain simulation of a folded touch screen stack-up including a touch sensor panel with planar electrodes according to examples of the disclosure. In some examples, touch screen 800 includes a neutral plane 822, which represents the layer where mechanical strain is reduced (or zero) when the display is bent or folded compared to other regions of the display. In some examples, neutral plane 822 has one or more characteristics of global neutral plane 720 of FIG. 7. As illustrated in FIG. 8B, the strain is lowest at neutral plane 822 and increases progressively as one moves away from this plane toward the outer layers of the stack-up. That is, as the distance from neutral plane 822 increases, the layers experience greater mechanical strain when the display is bent or folded. This occurs due to the physical nature of bending, where layers farther from the bend’s axis stretch (on the exterior side) or compress (on the interior side) more significantly than those at the bend’s axis. The outermost layers, therefore, are subjected to the highest levels of strain, which may lead to issues such as cracking, delamination, or other forms of stress-induced damage. Therefore, the most deformation-sensitive components, such as TFT bottom layer 804 and/or TFT top layer 806, may be disposed near neutral plane 822 to shield them from extreme mechanical stress.

FIG. 8C illustrates a close-up view of an example stress/strain simulation of a folded touch screen stack-up including a touch sensor panel with planar electrodes, focused on the touch sensor panel layers according to examples of the disclosure. The close-up view depicted in FIG. 8C corresponds to box 824 of FIG. 8B, showing only the strain simulation corresponding to first touch metal layer 812a, second touch metal layer 812b, and a thin passivation layer 816 (which is not separately labeled in FIG. 8C for simplicity, but is represented together with second touch metal layer 812b). The touch sensor panel layers, such as first touch metal layer 812a, second touch metal layer 812b, and passivation layer 816, may also be sensitive to deformation during bending. However, as illustrated in FIGS. 8A-8C, first touch metal layer 812a and second touch metal layer 812b are positioned further from neutral plane 822 and, as such, they are not in the region where mechanical strain is reduced. When the display bends, these layers experience higher levels of strain, leading to potential deformation. In particular, the planar structure of first touch metal layer 812a and second touch metal layer 812b, while optimal for flat, static touch sensing, is less adaptable to bending. The increased stress may lead to physical changes such as stretching, compressing, or micro-cracking, which may disrupt the continuity and uniformity of the conductive paths within these layers. Deformation of first and/or second touch metal layers 812a and 812b may cause an increase in the resistance of conductive traces, short-circuits, reduced touch sensor panel performance, altered capacitance, incomplete or faulty circuits, decrease in touch sensitivity, phantom touches where there is no actual user contact, and/or other issues which may compromise the structural integrity of the first and/or second touch metal layers 812a and 812b. In some examples, when second touch metal layer 812b is planar, the strain experienced by this layer under bending is relatively uniform across its extent.

FIG. 9A illustrates an example touch screen stack-up perpendicular to folding axis 610 shown in FIG. 6A including a touch sensor panel with non-planar electrodes according to examples of the disclosure. In some examples, touch screen 900 has one or more characteristics of touch screen 500 of FIG. 5, touch screen 700 of FIG. 7, and/or touch screen 800 of FIGS. 8A-8C. In some examples, touch screen 900 includes a substrate layer 902 (e.g., polyimide, polyethylene terephthalate, a printed circuit board, etc.) upon which display components can be formed or mounted. In some examples, the display components can be partially or fully embedded in substrate layer 902. In some examples, substrate layer 902 includes routing traces in one or more layers to route the display components to display driving circuitry (e.g., display driver 234). In some examples, touch screen 900 includes a TFT bottom layer 904 and a TFT top layer 906 referring to distinct sections of a TFT assembly that control the operation of the display pixels. In some examples, TFT bottom layer 904 and TFT top layer 906 have different characteristics. For example, TFT bottom layer 904 may house the main gate drivers and source lines necessary for controlling the basic on/off functionality of the pixels, while TFT bottom layer 906 may contain more refined control mechanisms, such as capacitors or additional transistors, which fine-tune the pixel operation for color accuracy and response time. In some examples, touch screen 900 includes a first passivation layer 908a, an encapsulation layer 910, and a second passivation layer 908b, that serve as protective layers within the stack-up, shielding the underlying electronic components from environmental factors. In some examples, passivation layers 908a and 908b differ in material composition to perform different protective roles.

In some examples, touch screen 900 includes a first touch metal layer 912a, which is one of the conductive layers within the stack-up. In some examples, electrodes formed on first touch metal layer 912a have one or more characteristics of touch electrodes 602 of FIG. 6A. In some examples, touch screen 900 includes a second touch metal layer 912b, which is one of the conductive layers within the stack-up. In some examples, electrodes formed on second touch metal layer 912b have one or more characteristics of touch electrodes 604 of FIG. 6A. In some examples, first touch metal layer 912a is planar, while second touch metal layer 912b is non-planar. In some examples, the non-planar design of second touch metal layer 912b includes wavy, corrugated, or otherwise geometrically varied patterns, which allows second touch metal layer 912b to better withstand mechanical strains associated with bending by distributing and relieving strain more effectively across the layer during bending compared with planar touch electrodes of FIG. 8A-8C. Some examples of non-planar structures that may be implemented in second touch metal layer 912b include, but are not limited to, wavy or sinusoidal patterns (e.g., continuous, smooth waves), accordion or zigzag patterns (e.g., sharp, angular bends), or other structures consisting of repeated curves that increase the flexibility and durability of the metal layer under bending. In some examples, the directionality of the non-planar structures such as wavy, sinusoidal, accordion, or zigzag patterns, extends perpendicularly from the plane of second touch metal layer 912b. Additionally or alternatively, in a three-dimensional context, the sinuous behavior of these patterns may manifest not only along the length of the trace (i.e., perpendicular to the folding axis) but also across its width, enhancing the layer’s overall resilience to bending. Implementing a wavy structure in second touch metal layer 912b involves introducing a series of alternating peaks and valleys across the surface of the conductive layer, where peaks are the highest points in the wavy pattern and valleys are the lowest points or valleys. In some examples, second touch metal layer 912b is designed to be at least partially planar with specific non-planar portions positioned within a defined threshold distance and planar portions positioned outside the threshold distance from the folding axis, such as folding zone 612 of FIG. 6A.

In some examples, the non-planar design of second touch metal layer 912b is manufactured via one or more of photolithography (e.g., using masks with gradient densities or customized patterns to create varied etching depths or structural heights or employing a step-and-repeat photolithography process to build up the non-planar structure in layers), nanoimprint lithography (e.g., developing custom stamps with the desired wavy patterns that may impress these shapes directly onto the conductive layer), laser ablation (e.g., adjusting laser parameters to selectively remove material to different depths), 3D printing or additive manufacturing (e.g., using conductive inks to directly print the wavy patterns layer by layer), or chemical vapor deposition with masks (e.g., utilizing masks or protective layers that only expose certain parts of the substrate).

In some examples, touch screen 900 includes an organic thin inter-layer dielectric (OTILD) 914, which acts as an insulating layer within the stack-up. In some examples, OTILD 914 is positioned between two conductive layers, such as first touch metal layer 912a and second touch metal layer 912b and prevents electrical crosstalk and short circuits between these conductive layers. In some examples, the non-planar design of second touch metal layer 912b introduces variable distances between first touch metal layer 912a and second touch metal layer 912b across OTILD 914.

In some examples, touch screen 900 includes a color filter/black matrix (CF/BM) layer 918. In some examples, a color filter portion of CF/BM layer 918 includes arrays of red, green, and blue subpixels that filter the white light emitted from the underlying layers into the primary colors needed for full-color display. In some examples, a black matrix portion of CF/BM layer 918 surrounds each subpixel to absorb stray light to enhance the contrast and sharpness of the image by preventing light from leaking between subpixels. In some examples, touch screen 900 includes a passivation layer 916, which optionally manages and enhances the optical characteristics of the display by filtering and/or adjusting the light before it passes through CF/BM layer 918 to ensure the colors displayed are vibrant, accurate, and uniform across the screen. In some examples, passivation layer 916 is positioned between second touch metal layer 912b and color filter layer 918. In some examples, touch screen 900 includes an over coat (OC) layer 920, which is the topmost layer in the stack-up and serves as a protective covering for the entire display assembly beneath it. In some examples, OC layer 920 is made from durable, transparent materials such as glass (e.g., hardened glass) or clear polymer composites that offer high resistance to scratches, impacts, and abrasion.

FIG. 9B illustrates an example stress/strain simulation of a folded touch screen stack-up including a touch sensor panel with non-planar electrodes according to examples of the disclosure. In some examples, touch screen 900 includes a neutral plane 922, which represents the layer where mechanical strain is reduced (or zero) when the display is bent or folded compared to other regions of the display. In some examples, neutral plane 922 has one or more characteristics of global neutral plane 720 of FIG. 7. As illustrated in FIG. 9B, the strain is lowest at neutral plane 922 and increases progressively as one moves away from this plane toward the outer layers of the stack-up. That is, as the distance from neutral plane 922 increases, the layers experience greater mechanical strain when the display is bent or folded. The outermost layers, therefore, are subjected to the highest levels of strain, which may lead to issues such as cracking, delamination, or other forms of stress-induced damage. Therefore, the most deformation-sensitive components, such as TFT bottom layer 904 and/or TFT top layer 906, may be disposed near neutral plane 922 to shield them from extreme mechanical stress.

FIG. 9C illustrates a close-up view of an example stress/strain simulation of a folded touch screen stack-up including a touch sensor panel with non-planar electrodes, focused on the touch sensor panel layers according to examples of the disclosure. The close-up view depicted in FIG. 9C corresponds to box 924 of FIG. 9B, showing only the strain simulation corresponding to first touch metal layer 912a, second touch metal layer 912b, and a thin passivation layer 916 (which is not separately labeled in FIG. 9C for simplicity, but is represented together with second touch metal layer 912b). The touch sensor panel layers, such as first touch metal layer 912a and second touch metal layer 912b, may also be sensitive to deformation during bending. As illustrated in FIGS. 9A-9C, first touch metal layer 912a and second touch metal layer 912b are positioned further from neutral plane 922 and, as such, they are not in the region where mechanical strain is reduced. When the display bends, these layers typically experience higher levels of strain, leading to potential deformation. However, whereas first touch metal layer 812a and second touch metal layer 812b of FIGS. 8A-8C have a planar structure, meaning they are less adaptable to bending, second touch metal layer 912b has a non-planar (e.g., wavy) structure, which allows first touch metal layer 912a and second touch metal layer 912b to more effectively absorb and distribute the mechanical stresses associated with bending.

In FIG. 8C, second touch metal layer 812b is planar, resulting in an even distribution of mechanical stress and strain during bending. The neutral plane in this configuration (e.g., neutral plane 822) is localized near TFT bottom layer 804 and TFT top layer 806, where the mechanical strain is reduced (or zero) due to their central positioning within the stack-up. In contrast, in FIG. 9C, second touch metal layer 912b is non-planar (e.g., wavy), which accommodates bending and creates a 3D local neutral plane 923 along the valleys of the wave. In particular, the valleys of the wave, such as valley 926 function as mini neutral zones where the material is less stretched or compressed, thereby maintaining structural integrity and functional reliability. In some examples, the valleys of the wavy second touch metal layer 912b (e.g., valley 926) experience tension (at or approaching zero strain), contrasting with the surrounding areas under compression, due to one or more characteristics of wavy second touch metal layer 912b.

Using finite element analysis (FEA), the strain distribution in both planar and non-planar configurations of second touch metal layers 812b and 912b can be simulated under identical bending conditions. FIGS. 8B, 8C, 9B, and 9C represent examples of such simulations. This analysis demonstrates that the non-planar, wavy structure exhibits lower strains throughout the material, with an overall average strain reduction of at least 25% in second touch metal layer 912b. In addition, the FEA simulation shows that the average strain reduction at the peaks, such as peak 928, of the wave of second touch metal layer 912b is at least 25% compared to second touch metal layer 812b, while the average strain reduction at the valleys of the wave of second touch metal layer 912b is at least 75% compared to second touch metal layer 812b. Furthermore, in the wavy structure of second touch metal layer 912b, the peaks and valleys experience less strain compared to the midline or midpoint areas of the waves, which are subjected to more neutral or transitional mechanical stresses.

In some examples, the amount of strain experienced by the wavy structure of second touch metal layer 912b depends on specific geometric characteristics of the wave, including the thickness, amplitude, and arc radius. For example, a lower ratio of thickness to arc radius increases the material’s ability to flex under stress, allowing for greater deformation before the material yields under stress, thus reducing the risk of damage (when other parameters are fixed). On the other hand, a higher ratio of thickness to arc radius results in less room for the material to maneuver under stress, possibly leading to higher strain concentrations and increased susceptibility to fatigue and failure. As another example, a higher ratio of amplitude to arc radius spreads the bending stress over a larger area, which can help in reducing the intensity of strain experienced by each segment of the wave, whereas a lower ratio of amplitude to arc radius concentrates stress over shorter distances, which may increase the strain on each wave segment and potentially lead to quicker material fatigue (when other parameters are fixed). As yet another example, in general, a larger arc radius offers a gentler curve that can bend more easily under stress, distributing the forces more evenly and reducing localized strain, whereas a smaller arc radius creates tighter curves that may concentrate stress at the curvature points, increasing the likelihood of exceeding the material’s elastic limit.

In some examples, the amount of strain experienced by first touch metal layer 912a and second touch metal layer 912b can be affected by the stiffness or modulus mismatch between these electrode layers and the surrounding organic layers, such as OTILD 914, where a larger mismatch facilitates a reduction in strain during bending or flexing. For example, when first touch metal layer 912a and second touch metal layer 912b are more flexible (e.g., having a lower modulus) compared to a relatively stiffer (higher modulus) OTILD 914, first touch metal layer 912a and second touch metal layer 912b can deform more readily under stress without transmitting excessive force to OTILD 914. This mismatch allows first touch metal layer 912a and second touch metal layer 912b to absorb bending stresses more efficiently, thereby reducing the localized strain within these layers. A stiffer OTILD 914 serves as a robust backing that supports first touch metal layer 912a and second touch metal layer 912b but does not itself deform easily. This setup restricts the extent of deformation transmitted back to first touch metal layer 912a and second touch metal layer 912b, limiting the strain they experience during bending.

Therefore, according to the above, some examples of the disclosure are directed to a foldable touch sensor panel. The foldable touch sensor panel includes a first plurality of touch electrodes along a first axis formed of a first conductive material disposed in a first conductive material layer and a second plurality of touch electrodes along a second axis formed of a second conductive material disposed in a second conductive material layer. The first plurality of touch electrodes along the first axis is parallel to a folding axis of the touch sensor panel and are planar or non-planar and the second plurality of touch electrodes along the second axis is non-parallel to the folding axis of the touch sensor panel and is at least partially non-planar.

Additionally or alternatively to one or more of the examples disclosed above, in some examples, the second axis is orthogonal to the first axis.

Additionally or alternatively to one or more of the examples disclosed above, in some examples, one or more non-planar portions of the second plurality of touch electrodes include a plurality of peaks and a plurality of valleys.

Additionally or alternatively to one or more of the examples disclosed above, in some examples, the second plurality of touch electrodes exhibit an average strain at the plurality of peaks when the foldable touch sensor panel is folded about the folding axis that is reduced by at least 25% compared to a planar implementation of the second plurality of touch electrodes and exhibit an average strain at the plurality of valleys when the foldable touch sensor panel is folded about the folding axis that is reduced by at least 75% compared to the planar implementation of the second plurality of touch electrodes.

Additionally or alternatively to one or more of the examples disclosed above, in some examples, the one or more non-planar portions of the second plurality of touch electrodes are patterned as a sinusoidal wave structure.

Additionally or alternatively to one or more of the examples disclosed above, in some examples, the plurality of peaks and the plurality of valleys of the sinusoidal wave structure exhibit less average strain than at a midline of the sinusoidal wave structure.

Additionally or alternatively to one or more of the examples disclosed above, in some examples, the plurality of peaks and the plurality of valleys create one or more neutral planes at the plurality of peaks and/or the plurality of valleys.

Additionally or alternatively to one or more of the examples disclosed above, in some examples, an average strain experienced by the second plurality of touch electrodes is based on at least one of an amplitude, wavelength, or arc radius of the sinusoidal wave structure.

Additionally or alternatively to one or more of the examples disclosed above, in some examples, the foldable touch sensor panel includes an organic material layer disposed between the first conductive material layer and the second conductive material. Additionally or alternatively to one or more of the examples disclosed above, in some examples, the first conductive material has a first stiffness, the second conductive material has a second stiffness, and the organic material layer has a third stiffness different from the first stiffness and the second stiffness by a threshold amount to reduce average strain of the first plurality of touch electrodes and the second plurality of electrodes.

Additionally or alternatively to one or more of the examples disclosed above, in some examples, the second plurality of touch electrodes exhibit an average strain when the foldable touch sensor panel is folded about the folding axis that is reduced by at least 25% compared to a planar implementation of the second plurality of touch electrodes.

Additionally or alternatively to one or more of the examples disclosed above, in some examples, the second plurality of touch electrodes along the second axis is at least partially planar, and the non-planar portions of the second plurality of touch electrodes are disposed within a threshold distance from the folding axis.

Additionally or alternatively to one or more of the examples disclosed above, in some examples, the threshold distance is 10 mm away from the folding axis in a direction of the second axis.

Additionally or alternatively to one or more of the examples disclosed above, in some examples, the first conductive material and the second conductive material are metal meshes and the first conductive material layer and the second conductive material layer are metal mesh layers.

Some examples are directed to a foldable touch screen. The foldable touch screen includes a display having an active area and a touch sensor panel. The touch sensor panel includes a first plurality of touch electrodes along a first axis formed of a first conductive material disposed in a first conductive material layer over the active area of the display and a second plurality of touch electrodes along a second axis formed of a second conductive material disposed in a second conductive material layer over the active area of the display. The first plurality of touch electrodes along the first axis is parallel to a folding axis of the touch screen and are planar or non-planar. The second plurality of touch electrodes along the second axis is non-parallel to the folding axis of the touch screen and is at least partially non-planar.

Additionally or alternatively to one or more of the examples disclosed above, in some examples, the display includes a substrate, a thin film transistor (TFT) layer, an organic light-emitting diode (OLED) layer, and an encapsulation layer. Additionally or alternatively to one or more of the examples disclosed above, in some examples, the TFT layer of the display corresponds to a first neutral plane. Additionally or alternatively to one or more of the examples disclosed above, in some examples, the touch sensor panel corresponds to a second neutral plane.

Additionally or alternatively to one or more of the examples disclosed above, in some examples, the foldable touch screen includes a passivation layer disposed between the second conductive material layer and a color filter layer, wherein the passivation layer includes peaks and valleys corresponding to peaks and valleys of the non-planar portions of the second plurality of touch electrodes.

Additionally or alternatively to one or more of the examples disclosed above, in some examples, the second plurality of touch electrodes exhibit an average strain at the peaks when the foldable touch screen is folded about the folding axis that is reduced by at least 25% compared to a planar implementation of the second plurality of touch electrodes and exhibit an average strain at the valleys when the foldable touch screen is folded about the folding axis that is reduced by at least 75% compared to the planar implementation of the second plurality of touch electrodes.

Additionally or alternatively to one or more of the examples disclosed above, in some examples, the peaks and the valleys create one or more neutral planes at the peaks and/or the valleys.

Additionally or alternatively to one or more of the examples disclosed above, in some examples, the second conductive material layer is further from an OLED layer than the first conductive material layer.

Some examples are directed to an electronic device. The electronic device includes an energy storage device, wireless communication circuitry, a display, and a touch sensor panel.

Although examples of this disclosure have been fully described with reference to the accompanying drawings, it is to be noted that various changes and modifications will become apparent to those skilled in the art. Such changes and modifications are to be understood as being included within the scope of examples of this disclosure as defined by the appended claims.

1. A foldable touch sensor panel comprising:
a first plurality of touch electrodes along a first axis formed of a first conductive material disposed in a first conductive material layer; and
a second plurality of touch electrodes along a second axis formed of a second conductive material disposed in a second conductive material layer;
wherein:
the first plurality of touch electrodes along the first axis is parallel to a folding axis of the touch sensor panel and are planar or non-planar; and
the second plurality of touch electrodes along the second axis is non-parallel to the folding axis of the touch sensor panel and is at least partially non-planar.

2. The foldable touch sensor panel of claim 1, wherein the second axis is orthogonal to the first axis.

3. The foldable touch sensor panel of claim 1, wherein one or more non-planar portions of the second plurality of touch electrodes include a plurality of peaks and a plurality of valleys.

4. The foldable touch sensor panel of claim 3, wherein the second plurality of touch electrodes exhibit an average strain at the plurality of peaks when the foldable touch sensor panel is folded about the folding axis that is reduced by at least 25% compared to a planar implementation of the second plurality of touch electrodes and exhibit an average strain at the plurality of valleys when the foldable touch sensor panel is folded about the folding axis that is reduced by at least 75% compared to the planar implementation of the second plurality of touch electrodes.

5. The foldable touch sensor panel of claim 3, wherein the one or more non-planar portions of the second plurality of touch electrodes are patterned as a sinusoidal wave structure.

6. The foldable touch sensor panel of claim 5, wherein the plurality of peaks and the plurality of valleys of the sinusoidal wave structure exhibit less average strain than at a midline of the sinusoidal wave structure.

7. The foldable touch sensor panel of claim 5, wherein an average strain experienced by the second plurality of touch electrodes is based on at least one of an amplitude, wavelength, or arc radius of the sinusoidal wave structure.

8. The foldable touch sensor panel of claim 3, wherein the plurality of peaks and the plurality of valleys create one or more neutral planes at the plurality of peaks and/or the plurality of valleys.

9. The foldable touch sensor panel of claim 1, further comprising:
an organic material layer disposed between the first conductive material layer and the second conductive material,
wherein the first conductive material has a first stiffness, the second conductive material has a second stiffness, and the organic material layer has a third stiffness different from the first stiffness and the second stiffness by a threshold amount to reduce an average strain of the first plurality of touch electrodes and the second plurality of touch electrodes.

10. The foldable touch sensor panel of claim 1, wherein the second plurality of touch electrodes exhibit an average strain when the foldable touch sensor panel is folded about the folding axis that is reduced by at least 25% compared to a planar implementation of the second plurality of touch electrodes.

11. The foldable touch sensor panel of claim 1, wherein the second plurality of touch electrodes along the second axis is at least partially planar, and the non-planar portions of the second plurality of touch electrodes are disposed within a threshold distance from the folding axis.

12. The foldable touch sensor panel of claim 11, wherein the threshold distance is 10 mm away from the folding axis in a direction of the second axis.

13. The foldable touch sensor panel of claim 1, wherein the first conductive material and the second conductive material are metal meshes and the first conductive material layer and the second conductive material layer are metal mesh layers.

14. A foldable touch screen comprising:
a display having an active area; and
a touch sensor panel comprising:
a first plurality of touch electrodes along a first axis formed of a first conductive material disposed in a first conductive material layer over the active area of the display; and
a second plurality of touch electrodes along a second axis formed of a second conductive material disposed in a second conductive material layer over the active area of the display;
wherein:
the first plurality of touch electrodes along the first axis is parallel to a folding axis of the foldable touch screen and are planar or non-planar; and
the second plurality of touch electrodes along the second axis is non-parallel to the folding axis of the foldable touch screen and is at least partially non-planar.

15. The foldable touch screen of claim 14, wherein:
the display includes a substrate, a thin film transistor (TFT) layer, an organic light-emitting diode (OLED) layer, and an encapsulation layer;
wherein the TFT layer of the display corresponds to a first neutral plane; and
the touch sensor panel corresponds to a second neutral plane.

16. The foldable touch screen of claim 14, further comprising:
a passivation layer disposed between the second conductive material layer and a color filter layer, wherein the passivation layer includes peaks and valleys corresponding to peaks and valleys of the non-planar portions of the second plurality of touch electrodes.

17. The foldable touch screen of claim 16, wherein the second plurality of touch electrodes exhibit an average strain at the peaks when the foldable touch screen is folded about the folding axis that is reduced by at least 25% compared to a planar implementation of the second plurality of touch electrodes and exhibit an average strain at the valleys when the foldable touch screen is folded about the folding axis that is reduced by at least 75% compared to the planar implementation of the second plurality of touch electrodes.

18. The foldable touch screen of claim 16, wherein the peaks and the valleys create one or more neutral planes at the peaks and/or the valleys.

19. The foldable touch screen of claim 14, wherein the second conductive material layer is further from an OLED layer than the first conductive material layer.

20. An electronic device comprising:
an energy storage device;
wireless communication circuitry;
a display; and
a touch sensor panel comprising:
a first plurality of touch electrodes along a first axis formed of a first conductive material disposed in a first conductive material layer; and
a second plurality of touch electrodes along a second axis formed of a second conductive material disposed in a second conductive material layer;
wherein:
the first plurality of touch electrodes along the first axis is parallel to a folding axis of the touch sensor panel and are planar or non-planar; and
the second plurality of touch electrodes along the second axis is non-parallel to the folding axis of the touch sensor panel and is at least partially non-planar.
